(19) United States
(12) Patent Application Publication
(10) Pub. No.: US 2020/0373394 A1
(43) Pub. Date: Nov. 26, 2020

(54) STRUCTURE FOR IMPROVING CHARACTERISTIC OF METAL OXIDE TFT AND MANUFACTURING METHOD THEREOF

(71) Applicant: Shenzhen China Star Optoelectronics Semiconductor Display Technology Co., Ltd., Shenzhen (CN)

(72) Inventors: Chunhsiung FANG, Shenzhen (CN); Yuanchun WU, Shenzhen (CN); Poyen Lu, Shenzhen (CN)

(73) Assignee: Shenzhen China Star Optoelectronics Semiconductor Display Technology Co., Ltd., Shenzhen (CN)

(21) Appl. No.: 16/605,210

(22) PCT Filed: Sep. 29, 2019
(86) PCT No.: PCT/CN2019/108890

§ 371 Date: Oct. 15, 2019

(30) Foreign Application Priority Data
May 22, 2019 (CN) 201910428309.3

(51) Int. Cl. H01L 29/22; H01L 29/66; H01L 29/786

(52) U.S. Cl. CPC H01L 29/22; H01L 29/786; H01L 29/66742

(57) ABSTRACT

The present invention provides a structure for improving the characteristics of a metal oxide TFT and a manufacturing method thereof. The structure includes a glass substrate, a buffer layer, a source metal layer, a drain metal layer, a metal oxide semiconductor layer, a gate insulating layer, a gate metal layer, a first conductor layer, a second conductor layer, and an inorganic protective layer. There is no overlapping area between the gate metal layer, the source metal layer and the drain metal layer. A distance between the gate metal layer and the source metal layer, and a distance between the gate metal layer and the drain metal layer are both less than 3 μm. Therefore, the metal oxide material of the metal oxide semiconductor layer can be reduced in variation due to process variation, thereby improving uniformity of the TFT on the entire glass substrate.

### FIELD OF INVENTION

The present invention relates to the field of display technologies, and in particular, to a structure for improving characteristics of a metal oxide thin film transistor (TFT) and a manufacturing method thereof.

### BACKGROUND OF INVENTION

Metal oxide TFT technologies, such as indium gallium zinc oxide (IGZO), indium zinc tin oxide (ITZO) and the like, compared with amorphous silicon thin film transistor (a-Si TFT) technology, have the following advantages: for example, higher carrier mobility, low leakage current, and better electrical stability, etc., so in recent years, they have been gradually applied to a driving circuit of an organic light emitting diode (OLED) display.

The three structures shown in FIG. 1, FIG. 2, and FIG. 3 are current commonly used TFT structures.

The first TFT structure illustrated in FIG. 1 is a bottom gate etch stop (Etching Stop) structure, referred to as an ESL structure. This structure is similar to the a-Si TFT structure, and has the characteristics of simple structure and good process stability. However, as shown by the dotted line (only a drain metal terminal is shown), a source metal layer, a drain metal layer, and a gate metal layer partially overlap in a vertical direction, so that a portion of the drain metal layer and the gate metal layer overlap to generate a parasitic capacitance (Cgd). Similarly, although not shown in the figure, the overlapping portion of the gate metal layer and the source metal layer generates parasitic capacitance (Cgs).

Due to the variability in the process, the metal overlap area of each place of the glass substrate will be somewhat different. Therefore, the degree of signal coupling effect caused by Cgd in each place is different, which affects the quality of the display screen.

The second TFT structure illustrated in FIG. 2 is a top gate coplanar structure. In order to cope with the difference in the process, the gate metal layer must overlap with a partial area of the source metal layer and the drain metal layer. Therefore, the same problem as the first structure described above is inevitable.

The third structure illustrated in FIG. 3 is a source/drain self-aligned top gate structure, and the gate metal layer of the structure does not overlap with the source metal layer and the drain metal layer. The area can avoid the aforementioned problems.

However, in the third structure illustrated in FIG. 3, the source metal layer and the drain metal layer of the partial area are composed of a metal oxide (such as IGZO, ITZO, etc.), and the metal oxide itself is a semiconductor and not a good conductor, it is necessary to use a gas plasma or ion implant technology to conduct this part of the metal oxide. This kind of conductor technology is still susceptible to the subsequent high-temperature process to change its conductivity, plus the pattern variability of each layer in the TFT process, from the carrier channel area to the source metal layer and the drain metal layer. The distance between the contact holes is greater than or equal to 3 μm. When the metal oxide is subjected to process variation, the resistance difference of each place of the glass substrate is large, so the current provided by the TFT structure in each place will be different for driving the OLED. The display will cause uneven brightness.

Therefore, there is a need to provide a structure for improving characteristics of a metal oxide TFT and a manufacturing method thereof to solve the problems of the prior art.

### SUMMARY OF INVENTION

An object of the present invention is to provide a structure for improving characteristics of a metal oxide thin film transistor (TFT) and a manufacturing method thereof, so as to shorten the distance between a gate metal layer, a source metal layer, and a drain metal layer, which is less than 3 μm, to reduce the difference in the resistance of the metal oxide material of the metal oxide semiconductor layer due to process variation, thereby improving the uniformity of the TFT on the entire glass substrate.

In order to achieve the above object, the present invention provides a structure for improving the characteristics of a metal oxide TFT. The structure for improving the characteristics of a metal oxide TFT comprises a glass substrate, a buffer layer, a source metal layer, a drain metal layer, a metal oxide semiconductor layer, a gate insulating layer, a gate metal layer, a first conductor layer, a second conductor layer, and an inorganic protective layer.

The buffer layer is disposed on the glass substrate. The source metal layer and the drain metal layer are disposed on the buffer layer opposite to each other at a certain distance apart. The metal oxide semiconductor layer is disposed between the source metal layer and the drain metal layer. The gate insulating layer and the gate metal layer are sequentially disposed on the metal oxide semiconductor layer from bottom to top. The first conductor layer is disposed between the source metal layer and the metal oxide semiconductor layer, and the second conductor layer is disposed between the drain metal layer and the metal oxide semiconductor layer. The inorganic protective layer is disposed on and covers the glass substrate, the buffer layer, the source metal layer, the drain metal layer, the gate metal layer, the first conductor layer, and the second conductor layer. The first conductor layer and the second conductor layer are obtained by processing the metal oxide semiconductor layer.

In one embodiment of the present invention, the gate metal layer does not overlap with the source metal layer and the drain metal layer, and a distance between the gate metal layer and the source metal layer, and a distance between the gate metal layer and the drain metal layer, are both less than 3 μm.

In one embodiment of the present invention, the gate insulating layer is merely disposed under the gate metal layer.

In one embodiment of the present invention, a sheet resistance of the metal oxide semiconductor layer under the gate metal layer >10⁸ Q/sq, a sheet resistance between the gate metal layer and the source metal layer, and a sheet resistance between the gate metal layer and the drain metal layer <3000 Ω/sq.

In order to achieve the above object, the present invention further provides a manufacturing method of a structure for improving characteristics of a metal oxide TFT. The manufacturing method of the structure for improving the characteristics of the metal oxide TFT comprises: (a) forming a buffer layer on a glass substrate by using a chemical vapor deposition technique; (b) forming a source metal layer and a drain metal layer on the buffer layer by using a sputtering technique, and patterning the source metal layer and the drain metal layer by photolithography; (c) forming a metal oxide semiconductor layer on the buffer layer, the source metal layer, and the drain metal layer by using a sputtering technique, and patterning the metal oxide semiconductor layer by photolithography; (d) forming a gate insulating layer on the buffer layer, the source metal layer, the drain metal layer, and the metal oxide semiconductor layer by using a chemical vapor deposition technique; (e) forming a gate metal layer on the buffer layer, the source metal layer, the drain metal layer, the metal oxide semiconductor layer, and the gate insulating layer by using a sputtering technique, patterning the gate metal layer by photolithography and etching the gate insulating layer outside the gate metal layer; (f) using the gate metal layer as a mask layer, and treating the metal oxide semiconductor layer disposed between the source metal layer and the drain metal layer into a first conductor layer and a second conductor layer by using a gas plasma or an ion implantation process; and (g) forming an inorganic protective layer disposed on the glass substrate, the buffer layer, the source metal layer, the drain metal layer, the gate metal layer, the first conductor layer, and the second conductor layer by using a chemical vapor deposition technique. Wherein a process of changing the metal oxide semiconductor layer disposed between the source metal layer and the drain metal layer to the first conductor layer and the second conductor layer is proceeded before or after removing the patterned photoresist of the gate metal layer.

In one embodiment of the present invention, the buffer layer is SiO2, SiNx, SiON or any composite layer of the above materials.

In one embodiment of the present invention, the metal material of the source metal layer and the drain metal layer is a metal such as Mo, Al, Ti, Cu or a composite layer.

In one embodiment of the present invention, the metal oxide material of the metal oxide semiconductor layer is IGZO or ITZO.

In one embodiment of the present invention, the gate insulating layer is SiO2, SiNx, SiON or any composite layer of the above materials.

In one embodiment of the present invention, the metal material of the gate metal layer is a metal such as Mo, Al, Ti, Cu or a composite layer.

In order to further understand the features and technical details of the present invention, please refer to the following detailed description and drawings regarding the present invention. The drawings are provided for reference and description only and are not intended to limit the present invention.

### DESCRIPTION OF DRAWINGS

The technical solutions and other advantageous effects of the present invention will be apparent from the following detailed description of embodiments of the invention.

In the drawings,

FIG. 1 is a schematic structural view of a bottom gate etch stop layer according to the prior art.

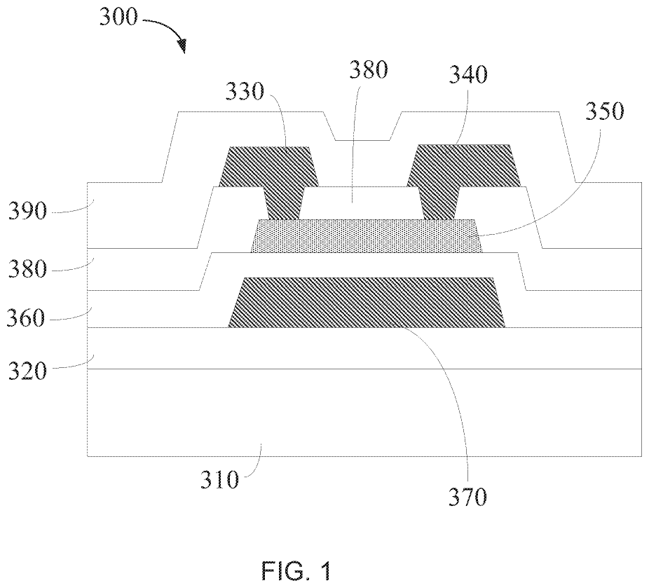

FIG. 2 is a schematic structural view of a top gate coplanar structure according to the prior art.

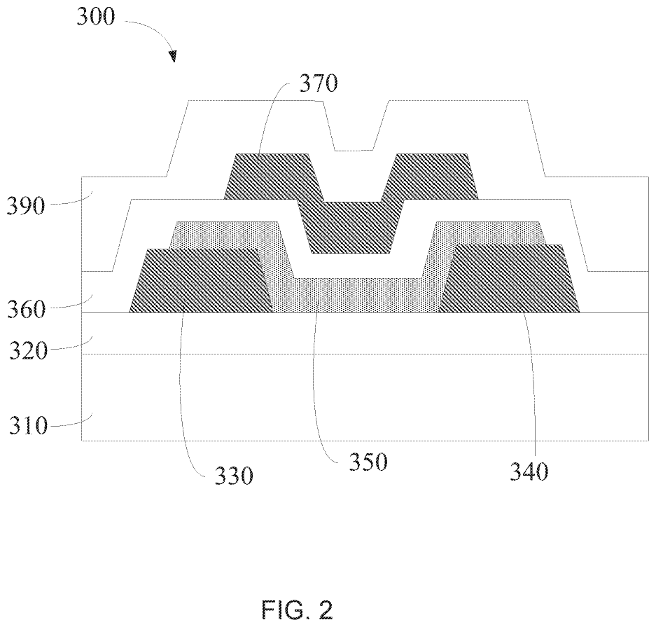

FIG. 3 is a schematic structural view of a source/drain self-aligned top gate structure according to the prior art.

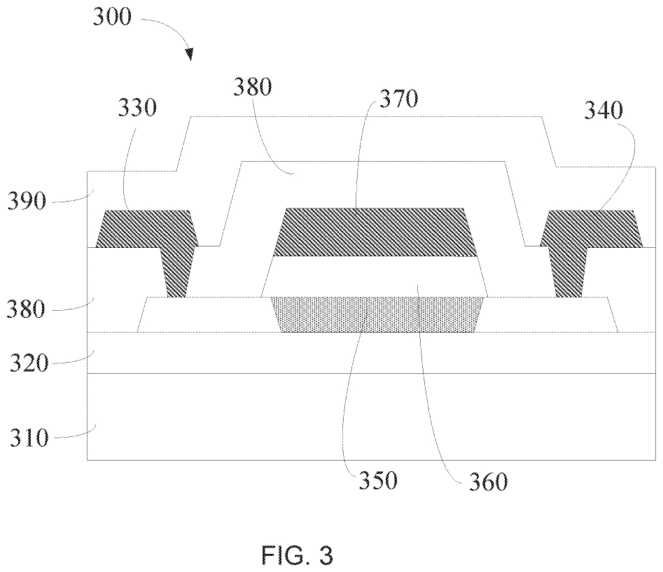

FIG. 4 is a schematic structural view of improving characteristics of a metal oxide TFT according to the present invention.

FIG. 5 is a diagram showing the steps of a manufacturing method for a metal oxide TFT according to the present invention.

FIG. 6 is a flow chart showing a manufacturing method for a metal oxide TFT according to the present invention.

### DETAILED DESCRIPTION OF PREFERRED EMBODIMENTS

The above and other objects, features, and advantages of the present invention will become more apparent from the understanding of the appended claims. Furthermore, the directional terms mentioned in the present invention, such as up, down, top, bottom, front, back, left, right, inner, outer, side, surrounding, center, horizontal, horizontal, vertical, longitudinal, axial, radial, uppermost or lowermost, etc., only refer to the direction of the additional schema. Therefore, the directional terminology used is for the purpose of illustration and understanding of the disclosure rather than limiting the disclosure.

In the figures, structurally similar elements are denoted by the same reference numerals.

The present invention is based on the improvement of the above second coplanar structure. In order to avoid the signal coupling phenomenon caused by Cgd and Cgs of the second structure, the present invention separates a gate metal layer from a source metal layer and a drain metal layer by a distance. As a result, there is no overlapping area between the gate metal layer, the source metal layer, and the drain metal layer, and thus the generation of Cgd/Cgs can be avoided.

However, the metal semiconductor material in the non-overlapping area has a higher electrical resistance, which suppresses the current of the TFT. Therefore, the problem is improved by gas plasma treatment or ion implantation process after patterning the gate metal.

On the other hand, since the structure of the present invention does not have the contact hole as in the above third self-aligned structure, only the alignment variation of the source metal layer, the drain metal layer, and the gate metal layer is considered, and thus a distance can be shortened. The distance between the gate metal layer, the source metal layer, and the drain metal layer is less than 3 μm, which reduces the difference in resistance of the metal oxide material of the metal oxide semiconductor layer due to process variation, thereby improving the entire uniformity of the TFT on the glass substrate.

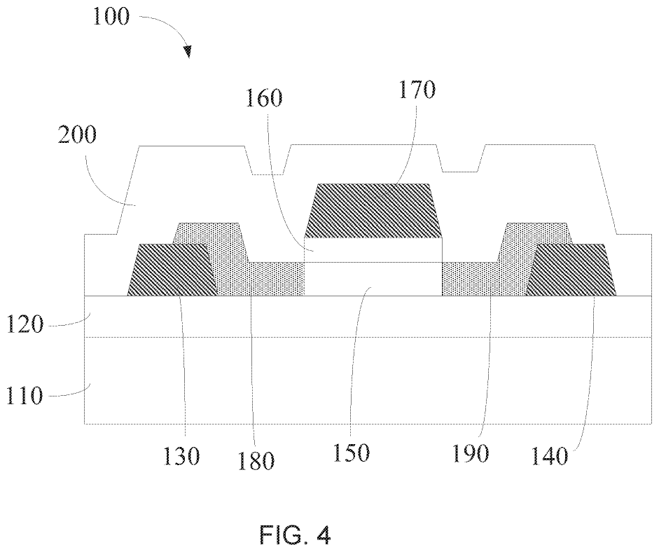

As shown in FIG. 4, a structure 100 for improving characteristics of a metal oxide thin film transistor (TFT) of the present invention comprises a glass substrate 110, a buffer layer 120, a source metal layer 130, a drain metal layer 140, a metal oxide semiconductor layer 150, a gate insulating layer 160, a gate metal layer 170, a first conductor layer 180, a second conductor layer 190, and an inorganic protective layer 200.

The buffer layer 120 is disposed on the glass substrate 110. The source metal layer 130 and the drain metal layer 140 are disposed on the buffer layer 120 opposite to each other at a certain distance apart. The metal oxide semiconductor layer 150 is disposed between the source metal layer 130 and the drain metal layer 140. The gate insulating layer 160 and the gate metal layer 170 are sequentially disposed on the metal oxide semiconductor layer 150 from bottom to top. The first conductor layer 180 is disposed between the source metal layer 130 and the metal oxide semiconductor layer 150, and the second conductor layer 190 is disposed between the drain metal layer 140 and the metal oxide semiconductor layer 150. The inorganic protective layer 200 is disposed on and covers the glass substrate 110, the buffer layer 120, the source metal layer 130, the drain metal layer 140, the gate metal layer 170, the first conductor layer 180, and the second conductor layer 190.

The first conductor layer 180 and the second conductor layer 190 are obtained by processing the metal oxide semiconductor layer 150.

As shown in FIG. 4, the gate metal layer 170 does not overlap with the source metal layer 130 and the drain metal layer 140, and a distance between the gate metal layer 170 and the source metal layer 130, and a distance between the gate metal layer 170 and the drain metal layer 140, are both less than 3 μm.

The gate insulating layer 160 is merely disposed under the gate metal layer 170.

A sheet t resistance of the metal oxide semiconductor layer 150 under the gate metal layer 170 >10⁸ Ω/sq, a sheet resistance between the gate metal layer 170 and the source metal layer 130, and a sheet resistance between the gate metal layer 170 and the drain metal layer 140 <3000 Ω/sq.

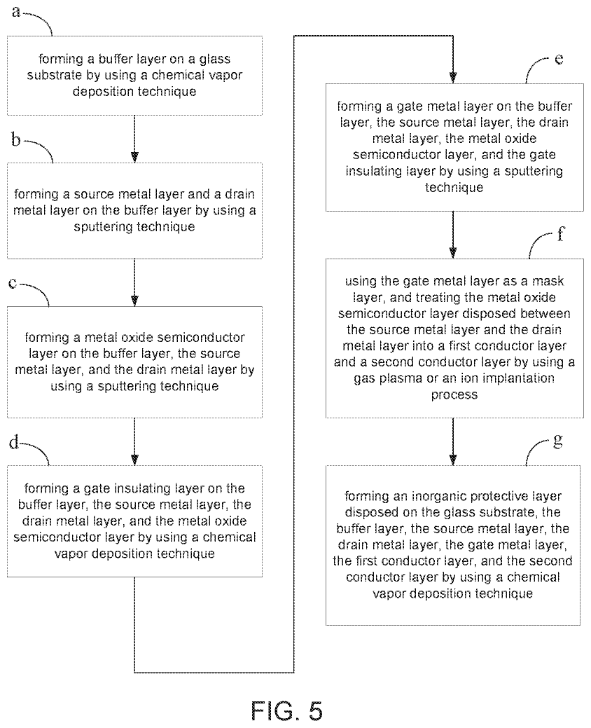

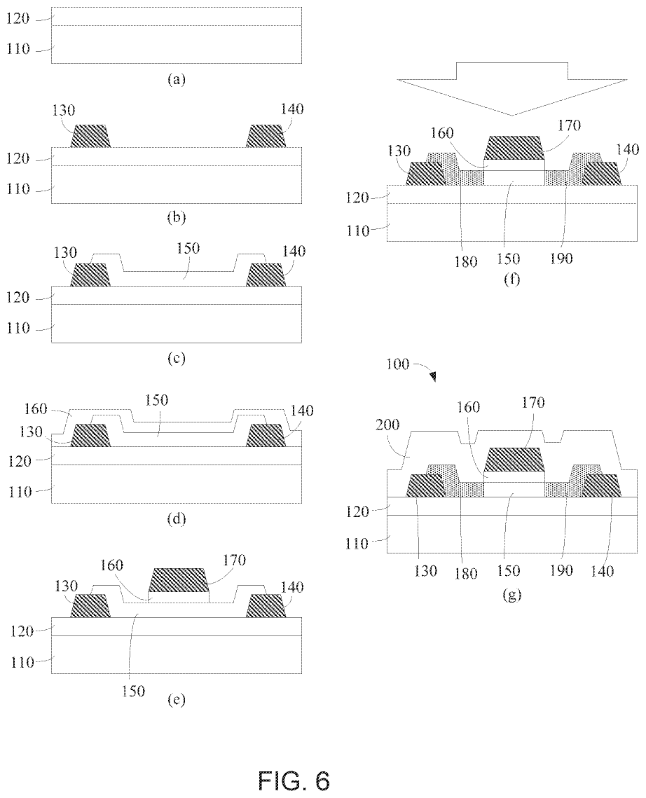

As shown in FIG. 5, the present invention further provides a manufacturing method of the structure 100 for improving characteristics of the metal oxide TFT. Please refer to FIG. 5 and FIG. 6 at the same time. The manufacturing method of the structure for improving the characteristics of the metal oxide TFT comprises: (a) forming a buffer layer 120 on a glass substrate 110 by using a chemical vapor deposition technique; (b) forming a source metal layer 130 and a drain metal layer 140 on the buffer layer 120 by using a sputtering technique, and patterning the source metal layer 130 and the drain metal layer 140 by photolithography; (c) forming a metal oxide semiconductor layer 150 on the buffer layer 120, the source metal layer 130, and the drain metal layer 140 by using a sputtering technique, and patterning the metal oxide semiconductor layer 150 by photolithography; (d) forming a gate insulating layer 160 on the buffer layer 120, the source metal layer 130, the drain metal layer 140, and the metal oxide semiconductor layer 150 by using a chemical vapor deposition technique; (e) forming a gate metal layer 170 on the buffer layer 120, the source metal layer 130, the drain metal layer 140, the metal oxide semiconductor layer 150, and the gate insulating layer 160 by using a sputtering technique, patterning the gate metal layer 170 by photolithography and etching the gate insulating layer 160 outside the gate metal layer 170; (f) using the gate metal layer 170 as a mask layer, and treating the metal oxide semiconductor layer 150 disposed between the source metal layer 130 and the drain metal layer 140 into a first conductor layer 180 and a second conductor layer 190 by using a gas plasma or an ion implantation process; and (g) forming an inorganic protective layer 200 disposed on the glass substrate 110, the buffer layer 120, the source metal layer 130, the drain metal layer 140, the gate metal layer 170, the first conductor layer 180, and the second conductor layer 190 by using a chemical vapor deposition technique.

In step (f), a process of changing the metal oxide semiconductor layer 150 disposed between the source metal layer 130 and the drain metal layer 140 to the first conductor layer 180 and the second conductor layer 190 is proceeded before or after removing the patterned photoresist of the gate metal layer 170, and the process gas can be Ar, He or N2, etc.

The buffer layer 120 is SiO2, SiNx, SiON or any composite layer of the above materials. The metal material of the source metal layer 130 and the drain metal layer 140 is a metal such as Mo, Al, Ti, Cu or a composite layer.

The metal oxide material of the metal oxide semiconductor layer 150 is IGZO or ITZO. The gate insulating layer 160 is SiO2, SiNx, SiON or any composite layer of the above materials. The metal material of the gate metal layer 170 is a metal such as Mo, Al, Ti, Cu or a composite layer.

In summary, due to the structure and method for improving the characteristics of the metal oxide TFT of the present invention, the gate metal layer 170 is separated from the source metal layer 130 and the drain metal layer 140 by a specific distance, there is no overlapping area between the gate metal layer 170, the source metal layer 130, and the drain metal layer 140, so that the generation of Cgd/Cgs is avoided.

In addition, the distance between the gate metal layer 170 and the source metal layer 130, and the distance between the gate metal layer 170 and the drain metal layer 140, are both less than 3 μm, so that the structure and method for improving the characteristics of the metal oxide TFT of the present invention can also effectively reduce the difference in the resistance of the metal oxide material of the metal oxide semiconductor layer 150 due to process variation, thereby improving the uniformity of the TFT on the entire glass substrate.

The present invention has been shown and described with respect to one or more embodiments, and equivalents and modifications will be apparent to those of ordinary skill in the art. The present invention includes all such modifications and variations, and is only limited by the scope of the appended claims. With particular regard to the various functions performed by the above-described components, the terms used to describe such components are intended to correspond to any component that performs the specified function of the component (e.g., which is functionally equivalent) (unless otherwise indicated). Even if it is structurally not identical to the disclosed structure for performing the functions in the exemplary implementation of the present specification shown herein. Moreover, although specific features of the specification have been disclosed with respect to only one of several implementations, such features may be combined with one or more other implementations as may be desired and advantageous for a given or particular application.

In the above, various other corresponding changes and modifications can be made according to the technical solutions and technical ideas of the present invention to those skilled in the art, and all such changes and modifications are within the scope of the claims of the present invention.

What is claimed is:

1. A structure for improving characteristics of a metal oxide thin film transistor (TFT), comprising:
a glass substrate;
a buffer layer disposed on the glass substrate;
a source metal layer and a drain metal layer, disposed on the buffer layer opposite to each other at a certain distance apart;
a metal oxide semiconductor layer, disposed between the source metal layer and the drain metal layer;
a gate insulating layer and a gate metal layer, sequentially disposed on the metal oxide semiconductor layer from bottom to top;
a first conductor layer and a second conductor layer, the first conductor layer disposed between the source metal layer and the metal oxide semiconductor layer, and the second conductor layer disposed between the drain metal layer and the metal oxide semiconductor layer; and
an inorganic protective layer disposed on and covering the glass substrate, the buffer layer, the source metal layer, the drain metal layer, the gate metal layer, the first conductor layer, and the second conductor layer;
wherein the first conductor layer and the second conductor layer are obtained by processing the metal oxide semiconductor layer.

2. The structure for improving the characteristics of the metal oxide TFT as claimed in claim 1, wherein the gate metal layer does not overlap with the source metal layer and the drain metal layer, and a distance between the gate metal layer and the source metal layer, and a distance between the gate metal layer and the drain metal layer, are both less than 3 μm.

3. The structure for improving the characteristics of the metal oxide TFT as claimed in claim 2, wherein the gate insulating layer is disposed only under the gate metal layer.

4. The structure for improving the characteristics of the metal oxide TFT as claimed in claim 3, wherein a sheet resistance of the metal oxide semiconductor layer under the gate metal layer >10⁸ Ω/sq, a sheet resistance between the gate metal layer and the source metal layer, and a sheet resistance between the gate metal layer and the drain metal layer <3000 Ω/sq.

5. A manufacturing method of a structure for improving characteristics of a metal oxide thin film transistor (TFT), comprising:
(a) forming a buffer layer on a glass substrate by using a chemical vapor deposition technique;
(b) forming a source metal layer and a drain metal layer on the buffer layer by using a sputtering technique, and patterning the source metal layer and the drain metal layer by photolithography;
(c) forming a metal oxide semiconductor layer on the buffer layer, the source metal layer, and the drain metal layer by using a sputtering technique, and patterning the metal oxide semiconductor layer by photolithography;
(d) forming a gate insulating layer on the buffer layer, the source metal layer, the drain metal layer, and the metal oxide semiconductor layer by using a chemical vapor deposition technique;
(e) forming a gate metal layer on the buffer layer, the source metal layer, the drain metal layer, the metal oxide semiconductor layer, and the gate insulating layer by using a sputtering technique, patterning the gate metal layer by photolithography and etching the gate insulating layer outside the gate metal layer;
(f) using the gate metal layer as a mask layer, and treating the metal oxide semiconductor layer disposed between the source metal layer and the drain metal layer into a first conductor layer and a second conductor layer by using a gas plasma or an ion implantation process; and
(g) forming an inorganic protective layer disposed on the glass substrate, the buffer layer, the source metal layer, the drain metal layer, the gate metal layer, the first conductor layer, and the second conductor layer by using a chemical vapor deposition technique;
wherein a process of changing the metal oxide semiconductor layer disposed between the source metal layer and the drain metal layer to the first conductor layer and the second conductor layer is proceeded before or after removing the patterned photoresist of the gate metal layer.

6. The manufacturing method of the structure for improving the characteristics of a metal oxide TFT as claimed in claim 5, wherein the buffer layer is SiO2, SiNx, SiON or any composite layer of the above materials.

7. The manufacturing method of the structure for improving the characteristics of a metal oxide TFT as claimed in claim 6, wherein the metal material of the source metal layer and the drain metal layer is a metal such as Mo, Al, Ti, Cu or a composite layer.

8. The manufacturing method of the structure for improving the characteristics of a metal oxide TFT as claimed in claim 7, wherein the metal oxide material of the metal oxide semiconductor layer is IGZO or ITZO.

9. The manufacturing method of the structure for improving the characteristics of a metal oxide TFT I as claimed in claim 8, wherein the gate insulating layer is SiO2, SiNx, SiON or any composite layer of the above materials.

10. The manufacturing method of the structure for improving the characteristics of a metal oxide TFT as claimed in claim 9, wherein the metal material of the gate metal layer is a metal such as Mo, Al, Ti, Cu or a composite layer.
